(19) United States
(12) Patent Application Publication
(10) Pub. No.: US 2009/0303806 A1
(43) Pub. Date: Dec. 10, 2009

(54) SYNCHRONOUS SEMICONDUCTOR MEMORY DEVICE

(75) Inventors: Sachiko EDO, Chuo-ku (JP); Toru ISHIKAWA, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/261,851

(22) Filed: Oct. 30, 2008

(30) Foreign Application Priority Data
Jun. 10, 2008 (JP) 2008-152112

(51) Int. Cl. G11C 7/00; G11C 8/18

(52) U.S. Cl. 365/189.12; 365/233.1; 365/219

(57) ABSTRACT

A semiconductor memory device may include,.but is not limited to, a storing unit and a selecting unit. The storing unit stores serial input data at at least one of a first type edge and a second type edge of a clock signal. The selecting unit receives the input data from the storing unit. The selecting unit selects the input data. The selecting unit outputs the selected input data in parallel.

### BACKGROUND OF THE INVENTION

1. Field of the Invention

The present invention generally relates to a semiconductor memory device More specifically, the present invention relates to a high speed synchronous semiconductor memory device that performs high speed data input and output operations in synchronization with high speed clock, wherein the high speed synchronous semiconductor memory is adapted for test operation using a non-advanced tester.

Priority is claimed on Japanese Patent Application No. 2008-152112, filed Jun. 10, 2008, the content of which is incorporated herein by reference.

2. Description of the Related Art

In recent years, there have been required higher speed performances of semiconductor memory devices such as dynamic random access memories (DRAMs). In accordance with Double Data Rate (DDR) 3, high data transfer rate of not lower than 1.6 G byte/sec. is required for the semiconductor memory device. In accordance with Graphic Double Data Rate (Graphic DDR) 5, high data transfer rate of not lower than 4.0 G byte/sec. is required for the semiconductor memory device. In general, testing such advanced high speed synchronous semiconductor memory device needs an advanced tester that is adapted for high frequency. Such advanced tester will be very expensive. Use of the advanced tester for testing the advanced high speed synchronous semiconductor memory device will increase the manufacturing cost and price of the semiconductor memory device.

Japanese Unexamined Patent Application, First Publication, No. 2006-277872 discloses that test mode operation is performed at a lower frequency than the normal frequency at which the normal operation is performed. In the test mode, data transfer for changing data is performed every two times or every four times. In the normal mode, the data transfer is performed every time. This test method allows non-advanced low speed tester to test the advanced high speed semiconductor memory. Such non-advanced low speed tester is adapted for low frequency but not for high frequency.

### SUMMARY

In one embodiment a semiconductor memory device may include, but is not limited to, a storing unit and a selecting unit. The storing unit stores serial input data at at least one of a first type edge and a second type edge of a clock signal. The selecting unit receives the input data from the storing unit. The selecting unit selects the input data. The selecting unit outputs the selected input data in parallel.

In another embodiment, a semiconductor memory device may include, but is not limited to, a selecting unit and an output unit. The selecting unit selects parallel output data. The output unit receives the selected output data from the selecting unit. The output unit outputs the selected output data in serial at first type and second type edges of a clock signal.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary plan view illustrating a block diagram illustrating an input circuit in a semiconductor memory device in accordance with a first preferred embodiment of the present invention;

FIG. 2 is a timing chart illustrating operations of the input circuit of FIG. 1 using a high speed tester;

FIG. 3 is a timing chart illustrating operations of the input circuit of FIG. 1 using a low speed tester;

FIG. 4 is a fragmentary plan view illustrating a block diagram illustrating an output circuit in a semiconductor memory device in accordance with a second preferred embodiment of the present invention;

FIG. 5 is a timing chart illustrating operations of the output circuit of FIG. 4;

FIGS. 6A and 6B are timing charts illustrating test operations in accordance with the related art;

FIG. 7 is a circuit diagram illustrating an input circuit in accordance with the related art;

FIG. 8 is a timing chart of the input circuit of FIG. 7;

FIG. 9 is a circuit diagram illustrating an output circuit in accordance with the related art;

FIG. 10 is a timing chart of the input circuit of FIG. 9;

FIGS. 11A and 11B are timing charts illustrating test operations in accordance with the related art; and

FIGS. 12A and 12B are timing charts illustrating test operations in accordance with the related art.

### DETAILED DESCRIPTION OF THE PREFERRED EMBODIMENTS

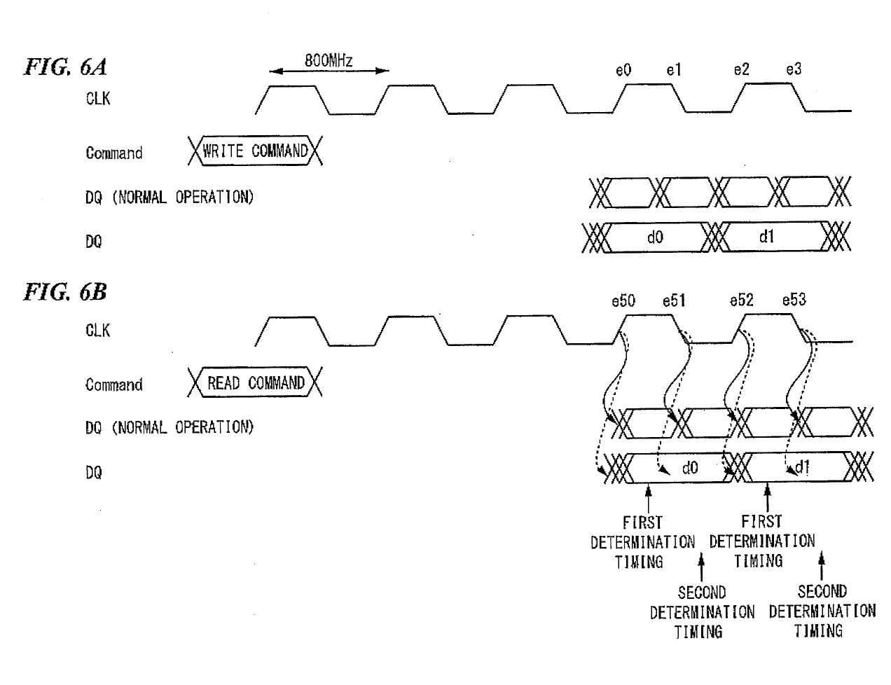

Before describing the present invention, the related art will be explained in detail with reference to FIGS. 6A, 6B, 7, 8, 9, 10, 11A, 11B, 12A and 12B, in order to facilitate the understanding of the present invention.

FIGS. 6A and 6B are timing charts illustrating test operations in accordance with the related art. With reference to FIG. 6A, test mode operation can be performed at a lower frequency than the normal frequency at which the normal operation is performed. In the test mode, data transfer for changing data is performed every two times, for example. In the normal mode, the data transfer is performed every time. While the frequency of a clock signal is 800 MHz, the frequency of data transition at the data input-output terminal DQ is 400 MHz. Tester that is used for implementing this test method will need a single high frequency test pin that is adapted to receive a high frequency clock CLK, and a number of low frequency test pins DQ that are adapted for input and output of data. Such tester is not expensive. Reducing the number of high frequency test pins of the tester reduces the price of the tester.

With reference to FIG. 6B, this method permits for determination of an expected value in read operation but only at an output from either one of the rising edge e50 and the falling edge e51 of the clock signal CLK. Thus, it generally needs to perform the test two times at different determination timings.

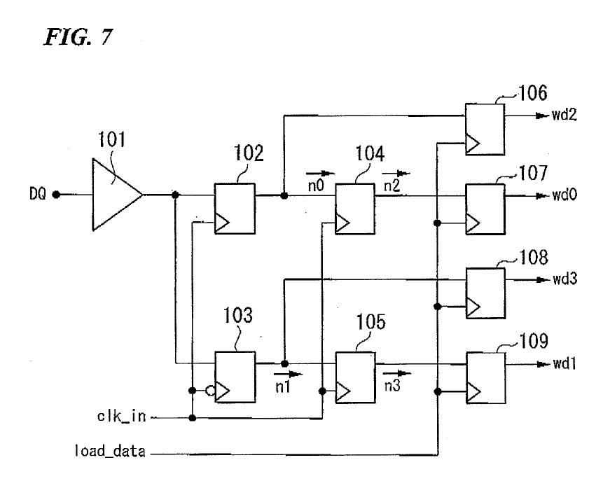

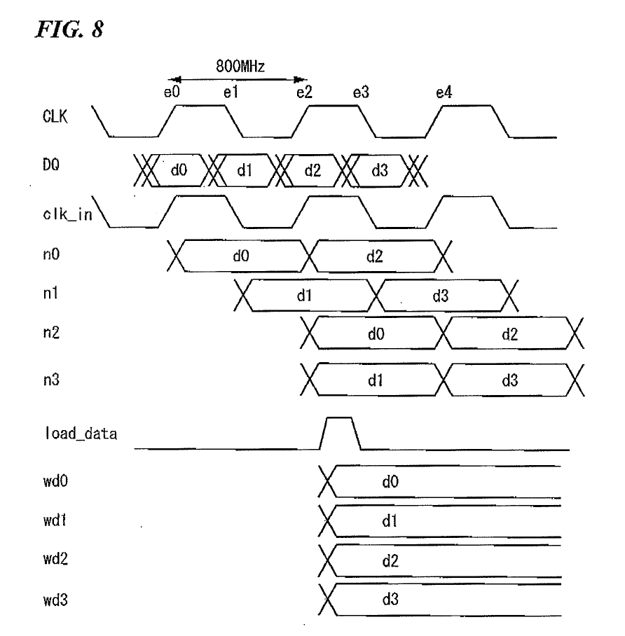

FIG. 7 is a circuit diagram illustrating an input circuit in accordance with the related art. FIG. 8 is a timing chart of the input circuit of FIG. 7. The input circuit of FIG. 7 includes a data input-output terminal DQ, an input buffer 101, and flip-flops 102, 103, 104, 105, 106, 107, 108, and 109. The data input-output terminal DQ receives an input of data d0. The data d0 is supplied through the input buffer 101 to the flip-flop 102. The flip-flop 102 latches the data d0 at the rising edge e0 of the clock input signal clk_in. The flip-flop 102 outputs the latched data d0 as an output n0.

The data input-output terminal DQ also receives an input of data d1. The data d1 is supplied through the input buffer 101 to the flip-flop 103. The flip-flop 103 latches the data d1 at the falling edge e1 of the clock input signal clk_in. The flip-flop 103 outputs the latched data d1 as an output n1.

The data input-output terminal DQ also receives an input of data d2. The data d2 is supplied through the input buffer 101 to the flip-flop 102. The flip-flop 102 latches the data d2 at the rising edge e2 of the clock input signal clk_in. The data input-output terminal DQ also receives an input of data d3. The data d3 is supplied through the input buffer 101 to the flip-flop 103. The flip-flop 103 latches the data d3 at the falling edge e3 of the clock input signal clk_in.

At the rising edge e2 of the clock input signal clk_in, the flip-flop 104 latches the latched data d0 that has been output as the output n0 from the flip-flop 102. Also, at the rising edge e2 of the clock input signal clk_in, the flip-flop 105 latches the latched data d1 that has been output as the output n1 from the flip-flop 103.

At the falling edge e3 of the clock input signal clk_in, a load data signal load_data is transitioned to HIGH, upon which flip-fops 107, 109, 106 and 108 latch data d0, d1, d2 and d3 that have been output from the flip-flops 104, 105, 102, and 103, respectively. Namely, at the falling edge e3 of the clock input signal clk_in, the flip-flop 107 latches the data d0 that has been output from the flip-flop 104. At the falling edge e3 of the clock input signal clk-in, the flip-flop 109 latches the data d1 that has been output from the flip-flop 105. At the falling edge e3 of the clock input signal clk_in, the flip-flop 106 latches the data d2 that has been output from the flip-flop 102. At the falling edge e3 of the clock input signal clk_in, the flip-flop 108 latches the data d3 that has been output from the flip-flop 103.

The data d0 is output as write data wd0 from the output terminal of the flip-flop 107, so that the write data wd0 is supplied as a write data signal to the memory cell area. The data d1 is output as write data wd1 from the output terminal of the flip-flop 109, so that the write data wd1 is supplied as a write data signal to the memory cell area. The data d2 is output as write data wd2 from the output terminal of the flip-flop 106, so that the write data wd2 is supplied as a write data signal to the memory cell area. The data d3 is output as write data wd3 from the output terminal of the flip-flop 108, so that the write data wd3 is supplied as a write data signal to the memory cell area.

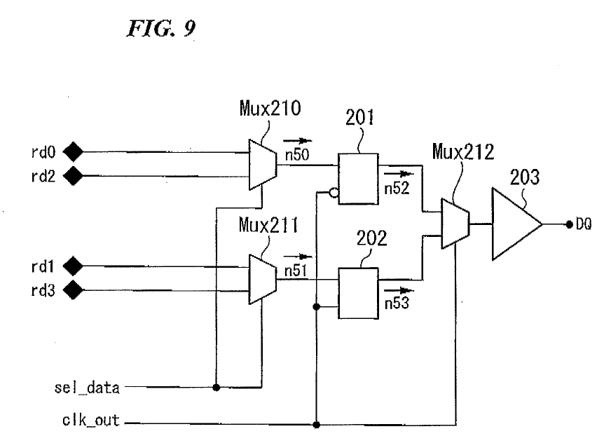

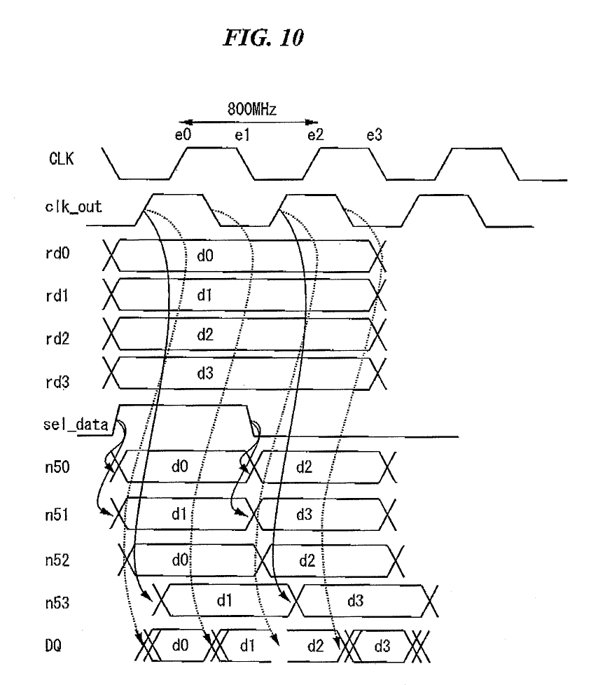

FIG. 9 is a circuit diagram illustrating an output circuit in accordance with the related art. FIG. 10 is a timing chart of the input circuit of FIG. 9. The output circuit of FIG. 9 is adapted to output read data rd0, rd1, rd2, and rd3 upon execution of the read command, wherein the read data rd0, rd1, rd2, and rd3 have been stored in the memory cell area in accordance with the write command.

The output circuit of FIG. 9 includes multiplexers Mux210, Mux211, and Mux212, latch circuits 201 and 202, and an output buffer 203. The multiplexer Mux210 selects read data rd0 as first data. The multiplexer Mux211 selects read data rd1 as first data. The multiplexer Mux210 selects read data rd2 as second data. The multiplexer Mux211 selects read data rd3 as second data. Namely, in the first half period, the multiplexer Mux210 selects the read data rd0 and outputs the read data rd0 as an output n50. In the second half period, the multiplexer Mux210 selects the read data rd2 and outputs the read data rd2 as the output n50. Also, in the first half period, the multiplexer Mux211 selects the read data rd1 and outputs the read data rd1 as an output n51. In the second half period, the multiplexer Mux211 selects the read data rd3 and outputs the read data rd3 as the output n51. The output n50 is supplied to the latch circuit 201. The output n51 is supplied to the latch circuit 202. The latch circuit 201 latches the output n50 in synchronization with the clock output signal clk_out. The latch circuit 202 latches the output n51 in synchronization with the clock output signal clk_out.

The multiplexer Mux212 selects the output n52 from the latch circuit 201 or the output n53 from the latch circuit 202, wherein the selection is made based on the clock output signal clk_out. The output from the multiplexer Mux212 is transferred through the output buffer 203 to the data input output terminal DQ.

In accordance with this method, values of the data d0, d1, d2, and d3 are such that the value of the data d0 is equal to the value of the data d1, and the value of the data d2 is equal to the value of the data d3, so as to reduce the frequency of the input output data.

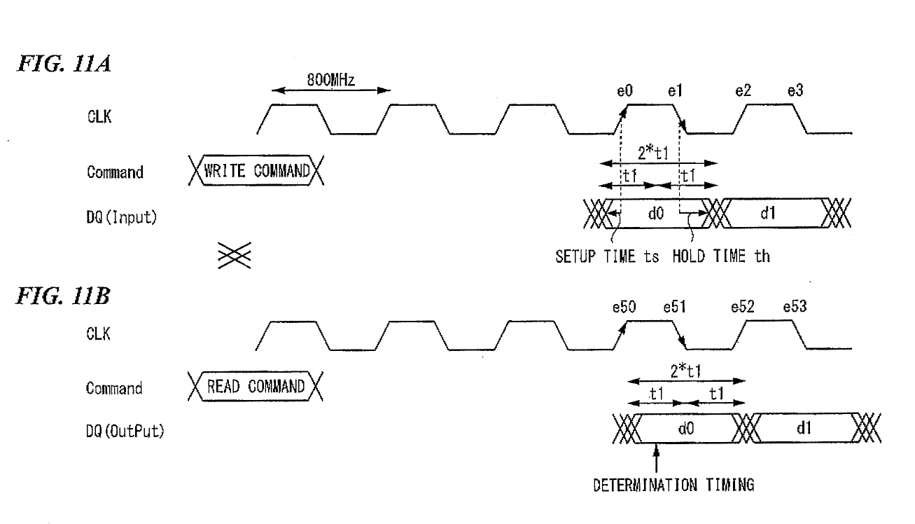

FIGS. 11A and 11B are timing charts illustrating test operations in accordance with the related art. With reference to FIG. 11A, a single set of data is input in a longer period of time which corresponds to the double of the term t1. The term t1 is a standard time period for input of a single set of data normally. For example, the term t1 may correspond to a half of the cycle of the clock signal CLK. The longer period of time will hereinafter be referred to as “2×t1”.

The semiconductor memory device is adapted to receive 2 bits for the longer time period “2×t1”. Not only a first set of data that is input at the rising edge e0 of the clock signal CLK but also a second set of data that is input at the falling edge e1 of the clock signal CLK are received by the semiconductor memory device and then both the first and second sets of data are stored therein.

With reference to FIG. 11B, if the semiconductor memory device in the write operation receives the data d0 at the rising edge e0 and the falling edge e1 of the clock signal CLK, the semiconductor memory device in the read operation outputs the data d0 for the longer time period “2×t1”. The longer time period, in which the value of the data remains unchanged, may permit the non-advanced lower speed tester to be used for the test of the advanced semiconductor memory device.

Use of the non-advanced lower speed tester has a limited performance that does not ensure adequate setup hold time at the rising edge e0 and the falling edge e1 of the clock signal CLK, thereby causing that the data d0 may not be stored in the semiconductor memory device.

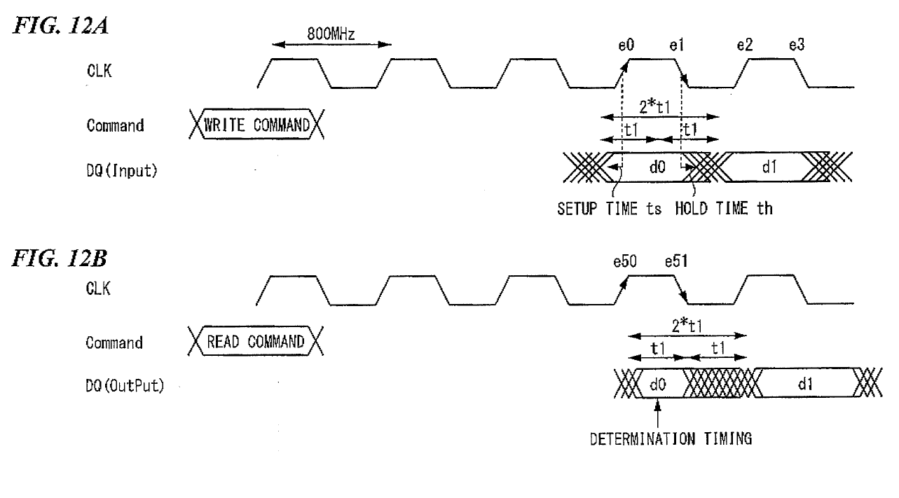

FIGS. 12A and 12B are timing charts illustrating test operations in accordance with the related art. With reference to FIG. 12A, no adequate hold time is given at the falling edge e1 of the clock signal CLK in the write operation. With reference to FIG. 12B, the data d0 is output for the shorter time period “1×t1”.

As shown in FIGS. 12A and 12B, if the non-advanced lower speed tester has the test limit of 400 MHz due to the limited test pins and test board, then the non-advanced lower speed tester is incapable of normally determining the output from the semiconductor memory device at a higher frequency of 800 MHz. The semiconductor memory device outputs the data d0 at the rising edge e50 of the clock signal CLK, while the non-advanced lower speed tester is incapable of normally determining the output from the semiconductor memory device.

This problem is caused by the facts that the semiconductor memory device has the internal clock at 800 MHz (1600 Mbps), while the non-advanced lower speed tester receives the data from the semiconductor memory device at 1600 Mbps.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

### First Embodiment

A synchronous semiconductor memory device receives a series of sets of data from the outside at a plurality of timings. The semiconductor memory device may include, but is not limited to, an input circuit that is adapted to supply only one or more selected sets of data to the inside of the semiconductor memory device, thereby allowing the semiconductor memory device to be tested by a non-advanced lower speed tester

A synchronous semiconductor memory device receives a series of sets of data from the outside at a plurality of timings. The semiconductor memory device may include, but is not limited to, an output circuit that is adapted to output only one or more selected sets of data to the outside of the semiconductor memory device, thereby allowing the semiconductor memory device to be tested by a non-advanced lower speed tester.

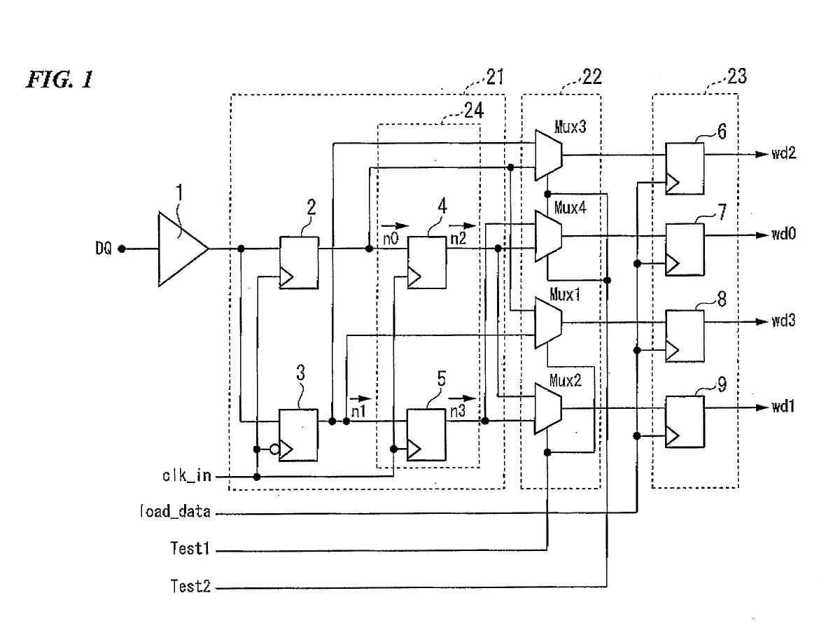

FIG. 1 is a fragmentary plan view illustrating a block diagram illustrating an input circuit in a semiconductor memory device in accordance with a first preferred embodiment of the present invention. The input circuit may perform as an input data storing and selecting unit in the semiconductor memory device. The input circuit may allow the semiconductor memory device to be tested by a non-advanced lower-speed tester which has a clock terminal which outputs a clock signal at a high frequency.

The input circuit may receive a clock input signal clk_in, an input data from a data input output terminal DQ, a load data signal load_data, a first test signal Test1 and a second test signal Test2. The first test signal Test1 may also perform as a first selecting signal. The second test signal Test2 may also perform as a second selecting signal. The clock input signal clk_in typically synchronizes with the clock signal CLK. In some cases, the clock input signal clk_in can be generated based on the clock signal CLK by a phase-locked loop circuit PLL.

The input data is input through the data input output terminal DQ. The input data may typically be serial data that is synchronized with the clock signal CLK. Namely, the input data may be a series of plural sets of data. The first and second test signals Test1 and Test2 may be supplied from the outside such as a tester in the test stage for testing the semiconductor memory device. The first and second test signals Test1 and Test2 may also be set by setting units such as fuse circuits or anti-fuse circuits that are included in the semiconductor memory device in the product shipment.

The input circuit may be adapted to receive serial data through the data input output terminal DQ and supply write data wd0, wd1, wd2, and wd3 as parallel data to memory cells of the semiconductor memory device. The write data wd0, wd1, wd2, and wd3 are stored in memory cells in accordance with the write command that is input into the semiconductor memory device.

### Configuration of Input Circuit

The configuration of the input circuit will be described. In some cases, the input circuit may include, but is not limited to, an input buffer 1, an input data storing unit 21, an input data selecting unit 22, and a storing and outputting unit 23. The input data storing unit 21 may include, but is not limited to, a shift register unit 24. The input data storing unit 21 may include, but is not limited to, flip-flop circuits 2, 3, 4, and 5. The shift register unit 24 may include, but is not limited to, the flip-flop circuits 4 and 5. The input data selecting unit 22 may include, but is not limited to, multiplexers Mux1, Mux2, Mux3, and Mux4. The storing and outputting unit 23 may include, but is not limited to, flip-flop circuits 6, 7, 8, and 9.

The flip-flop circuit 2 may perform as a first storing circuit. The flip-flop circuit 3 may perform as a second storing circuit. The flip-flop circuit 4 may perform as a third storing circuit. The flip-flop circuit 5 may perform as a fourth storing circuit.

The flip-flop circuit 6 may perform as a seventh storing circuit. The flip-flop circuit 7 may perform as an eighth storing circuit. The flip-flop circuit 8 may perform as a fifth storing circuit. The flip-flop circuit 9 may perform as a sixth storing circuit.

The multiplexer Mux1 may perform as a first selecting circuit. The multiplexer Mux2 may perform as a second selecting circuit. The multiplexer Mux3 may perform as a third selecting circuit. The multiplexer Mux4 may perform as a fourth selecting circuit.

The input buffer 1 has an input terminal which is connected to the data input output terminal DQ. The input buffer 1 has an output terminal which is connected to data input terminals of the flip-flop circuits 2 and 3. The flip-flop circuit 2 has a clock terminal that receives the clock input signal clk_in. The flip-flop circuit 3 has a clock terminal that receives the inversion of the clock input signal clk_in.

The flip-flop circuit 2 has a data output terminal which is connected to a data input terminal of the flip-flop circuit 4 and also connected to one input terminal of the multiplexer Mux1 and to one input terminal of the multiplexer Mux3.

The flip-flop circuit 3 has a data output terminal which is connected to a data input terminal of the flip-flop circuit 5 and also connected to the other input terminal of the multiplexer Mux1 and to the other input terminal of the multiplexer Mux3.

The flip-flop circuit 4 has a data output terminal which is connected to one input terminal of the multiplexer Mux2 and to one input terminal of the multiplexer Mux4. The flip-flop circuit 5 has a data output terminal which is connected to the other input terminal of the multiplexer Mux2 and to the other input terminal of the multiplexer Mux4.

The multiplexer Mux1 has a control terminal that receives the first test signal Test1. The multiplexer Mux2 has a control terminal that receives the first test signal Test1. The multiplexer Mux3 has a control terminal that receives the second test signal Test2. The multiplexer Mux4 has a control terminal that receives the second test signal Test2.

The multiplexer Mux1 has an output terminal which is connected to a data input terminal of the flip-flop circuit 8. The multiplexer Mux2 has an output terminal which is connected to a data input terminal of the flip-flop circuit 9. The multiplexer Mux3 has au output terminal which is connected to a data input terminal of the flip-flop circuit 6. The multiplexer Mux4 has an output terminal which is connected to a data input terminal of the flip-flop circuit 7.

The flip-flop circuit 6 outputs the stored data from the output terminal as a write data wd2 which is supplied to the memory cells of the semiconductor memory device. The flip-flop circuit 7 outputs the stored data from the output terminal as a write data wd0 which is supplied to the memory cells of the semiconductor memory device. The flip-flop circuit 8 outputs the stored data from the output terminal as a write data wd3 which is supplied to the memory cells of the semiconductor memory device. The flip-flop circuit 9 outputs the stored data from the output terminal as a write data wd1 which is supplied to the memory cells of the semiconductor memory device.

The flip-flop circuit 4 has a clock terminal that receives the clock input signal clk_in. The flip-flop circuit 5 has a clock terminal that receives the clock input signal clk_in. The flip-flop circuit 6 has a clock terminal that receives the load data signal load_data. The flip-flop circuit 7 has a clock terminal that receives the load data signal load_data. The flip-flop circuit 8 has a clock terminal that receives the load data signal load_data. The flip-flop circuit 9 has a clock terminal that receives the load data signal load_data.

The flip-flop circuit 2 stores the signal as input through the data input terminal and outputs the previously stored signal at the rising edge of the clock input signal clk_in. The flip-flop circuit 3 stores the signal as input through the data input terminal and outputs the previously stored signal at the falling edge of the clock input signal clk_in. The flip-flop circuit 4 stores the signal as input through the data input terminal and outputs the previously stored signal at the rising edge of the clock input signal clk_in. The flip-flop circuit 5 stores the signal as input through the data input terminal and outputs the previously stored signal at the rising edge of the clock input signal clk_in.

The flip-flop circuits 6-9 each store the signal as input through the data input terminal and outputs the previously stored signal at the rising edge of the load data signal load_data.

The multiplexer Mux1 selects one of the signals input to the one and other input terminals, based on the potential level of the first test signal Test1 that has been input into the control terminal thereof, so that the multiplexer Mux1 outputs the selected signal from the output terminal thereof. The multiplexer Mux2 selects one of the signals input to the one and other input terminals, based on the potential level of the first test signal Test1 that has been input into the control terminal thereof, so that the multiplexer Mux2 outputs the selected signal from the output terminal thereof. The multiplexer Mux3 selects one of the signals input to the one and other input terminals, based on the potential level of the second test signal Test2 that has been input into the control terminal thereof, so that the multiplexer Mux3 outputs the selected signal from the output terminal thereof. The multiplexer Mux4 selects one of the signals input to the one and other input terminals, based on the potential level of the second test signal Test2 that has been input into the control terminal thereof, so that the multiplexer Mux4 outputs the selected signal from the output terminal thereof. The high level and low level will hereinafter be referred to as “HIGH” and “LOW”.

The flip-flop circuits 2, 3, 4, and 5 co-operate as the input data storing unit 21. The input data storing unit 21 sequentially stores the input data, which has been input through the data input output terminal DQ, both at the rising edge of the clock input signal clk_in and at the falling edge of the clock input signal clk_in.

The flip-flop circuits 4 and 5 co-operate as the shift register unit 24. The shift register unit 24 sequentially stores the input data, which has been stored in the flip-flop circuits 2 and 3, at the rising edge of the clock input signal clk_in.

The multiplexers Mux1, Mux2, Mux3, and Mux4 co-operate as the input data selecting unit 22. The input data selecting unit 22 selects the input data stored in the input data storing unit 21 and outputs the selected data. The input data selecting unit 22 selects one of the input data stored in the flip-flop circuit 2 and the input data stored in the flip-flop circuit 3. The input data selecting unit 22 also selects one of the input data stored in the flip-flop circuit 4 and the input data stored in the flip-flop circuit 5 in the shift register 24.

The flip-flop circuits 6, 7, 8, and 9 co-operate as the storing and outputting unit 23. The storing and outputting unit 23 receives the selected data from the input data selecting unit 22, so that the storing and outputting unit 23 stores the selected data at the rising edge of the load data signal load_data and then output the write data wd0, wd1, wd2, and wd3 as parallel data.

Operation of Input Circuit using High Speed Tester:

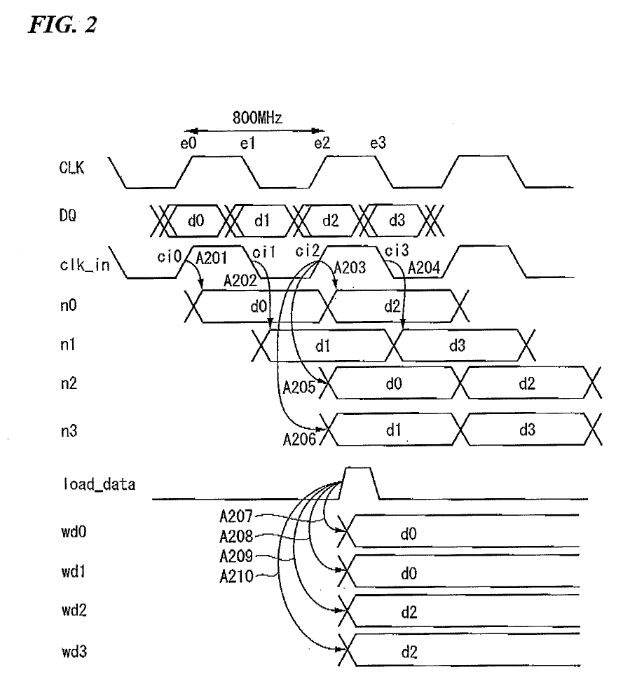

FIG. 2 is a timing chart illustrating operations of the input circuit of FIG. 1 using a high speed tester. The flip-flop circuit 2 stores the data d0, which has been input through the data input output terminal DQ, at the rising edge ci0 of the clock input signal clk_in, so that the flip-flop circuit 2 outputs the stored data d0 as the output n0 (see A201). The clock input signal clk_in is synchronized with the clock signal CLK. The rising edge ci0 of the clock input signal clk_in corresponds to the rising edge of the clock signal CLK.

The flip-flop circuit 3 stores the data d1, which has been input though the data input output terminal DQ, at the failing edge ci1 of the clock input signal clk_in, so that the flip-flop circuit 3 outputs the stored data d1 as the output n1 (see A202).

The flip-flop circuit 2 stores the data d2, which has been input through the data input output terminal DQ, at the rising edge ci2 of the clock input signal clk_in (see A203). The flip-flop circuit 3 stores the data d3, which has been input through the data input output terminal DQ, at the falling edge ci3 of the clock input signal clk_in (see A204).

At the rising edge ci2 of the clock input signal clk_in, the output data d0 from the flip-flop circuit 2 is stored in the flip-flop circuit 4, so that the output data d0 is output as the output n2 from the flip-flop circuit 4 (see A205). At the rising edge ci2 of the clock input signal clk_in the output data d1 from the flip-flop circuit 3 is stored in the flip-flop circuit 5, so that the output data d1 is output as the output n3 from the flip-flop circuit 5 (see A206).

At the falling edge ci3 of the clock input signal clk_in, the load data load_data is transitioned to “HIGH”, so that the flip-flop circuit 6, 7, 8 and 9 store plural sets of the selected data that have been supplied from the multiplexers Mux3, Mux4, Mux1, and Mux2, respectively. The flip-flop circuit 6, 7, 8 and 9 output plural sets of the write data w2, wd0, wd3 and wd1 as parallel data, respectively (A207, A208, A209, and A210).

The input circuit includes both the multiplexers Mux2 and Mux1, wherein the multiplexer Mux2 selects either one of the outputs n2 and n3 from the flip-flop circuits 4 and 5, so that the multiplexer Mux2 outputs the write data wd1, and the multiplexer Mux1 selects either one of the outputs n0 and n1 from the flip-flop circuits 2 and 3, so that the multiplexer Mux1 outputs the write data wd3. Thus, when the first test signal Test1 is “HIGH”, the output n2 is captured as the write data wd1, and the output n0 is captured as the write data wd3, so that the output d0 is output as the write data wd0 and wd1, and the data d2 is output as the write data wd2 and wd3.

Operation of Input Circuit using Law Speed Tester:

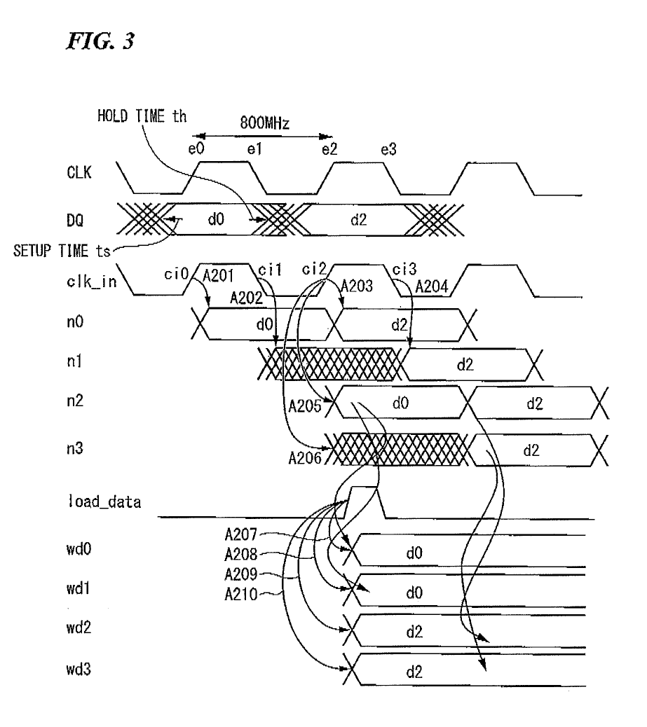

FIG. 3 is a timing chart illustrating operations of the input circuit of FIG. 1 using a low speed tester. The same signals and operations in FIG. 3 as those in FIG. 2 are allocated with the same reference numbers and duplicate descriptions will be omitted.

FIG. 3 shows the operations of the input circuit using the low speed tester which is lower in performance than the high speed tester which is used for the above-described operations of the input circuit shown in FIG. 2. The use of the low speed tester causes show transfer rate of data that has been input through the data input output terminal DQ. The low speed tester output the data from the data input output terminal DQ at low speed, while the low speed tester outputs the lock signal CLK at the same high frequency.

In FIG. 3, the low speed tester is used to input data through the data input output terminal at a low speed. The input circuit can not ensure the adequate hold time at the falling edge ci1 of the clock input signal clk_in. Thus, the output n1 from the flip-flop circuit 3 is undefined, so that the output n3 from the flip-flop circuit 5 is also undefined.

As described above with reference to FIG. 2, the input circuit receives the data that has been input through the data input output terminal DQ, and the input circuit selects the data d0 and d2 only which are sampled or stored at the rising edges ci0 and ci2 (the rising edges e0 and e2), so that the input circuit outputs the selected data d0 and d2 as write data wd0, wd1, wd2, and wd3 as the parallel data.

With reference to FIG. 3, the low speed tester is used to input data through the data input output terminal DQ at a lower data rate. In this case, the input circuit of the semiconductor memory device has the limitation of test pin performance which may not ensure the adequate setup hold time for sampling or storing the data at both sequential rising and falling edges e0 and e1 of the clock signal CLK. The input circuit allows that inadequate setup hold time for sampling or storing the data at both sequential rising and falling edges e0 and e1 results in undefined data input into the input circuit of the semiconductor memory device.

However, the input circuit allows that adequate setup hold time for sampling or storing the data at at least one of the sequential rising and falling edges e0 and e1 results in that the input circuit outputs the normal values of data as write data wd0, wd1, wd2, and wd3, without outputting any undefined values of data. Namely, the input circuit allows writing, in memory cells, the normal values of data such as data d0, d1, d2, and d3 as write data wd0, wd1, wd2, and wd3, without writing any undefined values of data therein.

When the input circuit of FIG. 1 is used to supply the normal data to memory cells so that the normal data is stored in the memory cells, the output circuit described with reference to FIG. 9 can be used to read the data out of the memory cells so that the output circuit receives the input of the data d0, d1, d2, and d3 as the read data rd0, rd1, rd2, and rd3.

The output circuit of FIG. 9 used in combination with the input circuit of FIG. 1 will output the same value of data for the longer time period “2×t1” as shown in FIG. 11B. Thus, the data as output from the output circuit of FIG. 9 allows the non-advanced lower speed tester to accurately determine the data. Namely, the input circuit of FIG. 1 is used to store the same values of data in memory cells so as to allow the non-advanced lower speed tester to accurately determine the data that has been read out of the memory cells.

The use of the input circuit of FIG. 1 in combination with the output circuit of FIG. 9 allows the non-advanced lower speed tester to accurately test the semiconductor memory device both in write operation and read operation.

The input circuit of FIG. 1 is adapted to capture the data at the rising edges e0 and e2 of the clock signal CLK when the first test signal Test1 is HIGH, thereby allowing the non-advanced lower speed tester to accurately test the semiconductor memory device. The input circuit of FIG. 1 is adapted to capture the data at the falling edges e1 and e3 of the clock signal CLK when the second test signal Test2 is HIGH, thereby allowing the non-advanced lower speed tester to accurately test the semiconductor memory device. The input circuit of FIG. 1 allows the non-advanced lower speed tester to accurately test the semiconductor memory device either when the first test signal Test1 is HIGH or when the second test signal Test2 is HIGH.

The operations of the input circuit of FIG. 1 in test mode have been described. The input circuit of FIG. 1 is operable in normal mode. The input circuit of FIG. 1 is adapted to output the data d0, d1, d2, and d3 as the write data wd0, wd1, wd2, and wd3 in accordance with the first test signal Test1 and the second test signal Test2. The input circuit of FIG. 1 can operate in the normal mode.

The combination of the first test signal Test1 and the second test signal Test2 controls or switches the operation mode between the test mode and the normal mode.

Whereas the shift register 24 has one stage including the flip-flop circuits 4 and 5 for the flip-flop circuits 2 and 3 as shown in FIG. 1, the number of the stages of the shift register 24 is optional.

### Second Embodiment

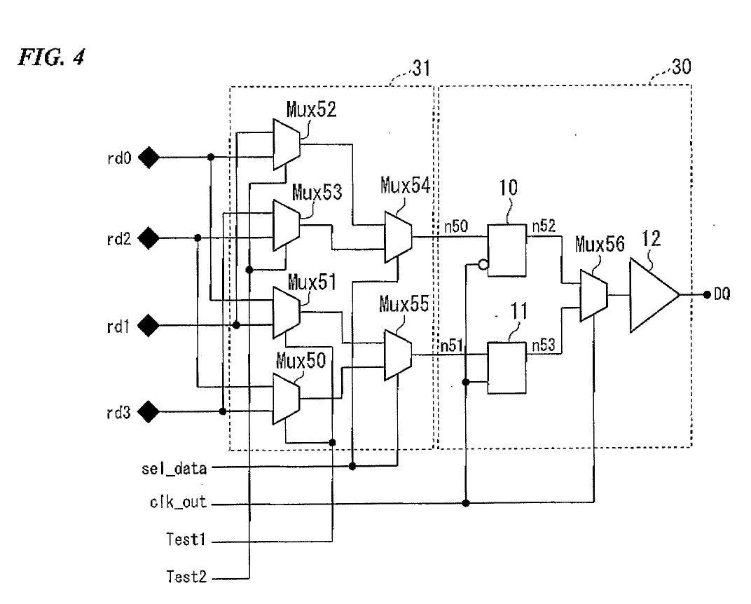

FIG. 4 is a fragmentary plan view illustrating a block diagram illustrating an output circuit in a semiconductor memory device in accordance with a second preferred embodiment of the present invention. The output circuit may allow the semiconductor memory device to be tested by a non-advanced lower-speed tester which has a clock terminal which outputs a clock signal at a high frequency.

The output circuit may receive a read data rd0 as a first output data, a read data rd1 as a second output data, a read data rd2 as a third output data, a read data rd3 as a fourth output data, a clock output signal clk₁₃ out, an output data selecting signal se1_data, a first test signal Test1 and a second test signal Test2.

The read data rd0, rd1, rd2, and rd3 are the data that have been read out of memory cells. The read data rd0, rd1, rd2, and rd3 are parallel data. The clock output signal clk_out is synchronized with the clock signal CLK. In some cases, the clock output signal clk_out can be generated based on the clock signal CLK by a phase-locked loop circuit PLL. The output data selecting signal se1_data may be either a signal that is input from the outside of the semiconductor memory device or a signal generated by the controller of the semiconductor memory device from an external signal that has been input from the outside of the semiconductor memory device. The output data selecting signal se1_data may be “HIGH” in a period of time which corresponds to one cycle of the clock signal CLK.

The first and second test signals Test1 and Test2 in this embodiment may be identical with the first and second test signals Test1 and Test2 in the first embodiment.

The output circuit may be adapted to receive read data wd0, wd1, wd2, and wd3 as parallel data. The output circuit performs selection of the read data wd0, wd1, wd2, and wd3 in accordance with the first test signal Test1 and the second test signal Test2, so that the output circuit outputs the serial data that from the data input output terminal DQ, wherein the serial data is synchronized with the clock output signal clk_out. The output circuit performs selection of the read data wd0, wd1, wd2, and wd3 in response to the potential level of the output data selecting signal se1_data.

In accordance with the above embodiment, the input data is stored at the rising edge and the falling edge of the clock signal. The stored data can be read out of memory cells for every other bit, thereby allowing a non-advanced lower speed tester to test the advanced semiconductor memory device. Parts of the stored input data may be read at an edge selected from every group that includes a predetermined number of sequential edges of the clock signal. In some cases, parts of the stored input data may be read at the every n-th riding edge of the clock signal. In other cases, parts of the stored input data may be read at the every n-th falling edge of the clock signal. In still other cases, parts of the input data may be stored at an edge selected from every group that includes a predetermined number of sequential edges of the clock signal, thereby reducing the amount of data that needs to be stored. In yet other cases, parts of the input data may be stored at the every n-th riding edge of the clock signal, thereby reducing the amount of data that needs to be stored. In other cases, parts of the input data may be stored at the every n-th falling edge of the clock signal, thereby reducing the amount of data that needs to be stored. In still other cases, parts of the input data may be stored at the every n-th riding edge of the clock signal, thereby reducing the amount of data that needs to be stored. In yet other cases, parts of the input data may be stored at the every n-th falling edge of the clock signal, thereby reducing the amount of data that needs to be stored. Reduction to the amount of data that needs to be stored reduces the necessary circuit scale of the input data memory 21.

### Configuration of Output Circuit:

The configuration of the output circuit will be described. In some cases, the output circuit may include, but is not limited to, a data output unit 30, and an output data selecting unit 31. The output data selecting unit 31 may include, but is not limited to, multiplexers Mux50, Mux51, Mux52, Mux53, Mux54 and Mux55. The data output unit 30 may includes but is not limited to, latch circuits 10 and 11, a multiplexer Mux56, and an output buffer 12.

The multiplexer Mux50 may perform as an eleventh selecting circuit. The multiplexer Mux51 may perform as a tenth selecting circuit. The multiplexer Mux52 may perform as an eighth selecting circuit. The multiplexer Mux53 may perform as a ninth selecting circuit. The multiplexer Mux54 may perform as a fifth selecting circuit. The multiplexer Mux55 may perform as a sixth selecting circuit. The multiplexer Mux56 may perform as a seventh selecting circuit

The latch circuit 10 may perform as a ninth storing circuit. The latch circuit 11 may perform as a tenth storing circuit.

The multiplexer Mux50 has a first input terminal that receives the read data rd2. The multiplexer Mux50 has a second input terminal that receives the read data rd3. The multiplexer Mux51 has a first input terminal that receives the read data rd0. The multiplexer Mux51 has a second input terminal that receives the read data rd1. The multiplexer Mux52 has a first input terminal that receives the read data rd1. The multiplexer Mux52 has a second input terminal that receives the read data rd0. The multiplexer Mux53 has a first input terminal that receives the read data rd3. The multiplexer Mux53 has a second input terminal that receives the read data rd2.

The multiplexer Mux52 has an output terminal that is connected to a first input terminal of the multiplexer Mux54. The multiplexer Mux53 has an output terminal that is connected to a second input terminal of the multiplexer Mux54. The multiplexer Mux51 has an output terminal that is connected to a first input terminal of the multiplexer Mux55. The multiplexer Mux50 has an output terminal that is connected to a second input terminal of the multiplexer Mux55.

The multiplexer Mux54 has an output terminal that is connected to a data input terminal of the latch circuit 10. The multiplexer Mux55 has an output terminal that is connected to a data input terminal of the latch circuit 11.

The latch circuit 10 has an output terminal that is connected to a first input terminal of the multiplexer 56. The latch circuit 11 has an output terminal that is connected to a second input terminal of the multiplexer 56. The multiplexer 56 has an output terminal that is connected to an input terminal of the output buffer 12. The output buffer 12 has an output terminal that is connected to the data input output terminal DQ.

The multiplexer Mux50 has a control terminal that receives the first test signal Test1. The multiplexer Mux51 has a control terminal that receives the first test signal Test1. The multiplexer Mux52 has a control terminal that receives the second test signal Test2. The multiplexer Mux53 has a control terminal that receives the second test signal Test2. The multiplexer Mux54 has a control terminal that receives the output data selecting signal se1_data. The multiplexer Mux55 has a control terminal that receives the output data selecting signal se1_data.

The latch circuit 11 has a latch enable terminal that receives the clock output signal clk_out. The multiplexer Mux56 has a control terminal that receives the clock output signal clk_out. The latch circuit 10 has a latch enable terminal that receives the inversion of the clock output signal clk_out.

The multiplexers Mux50, Mux51, Mux52, Mux53, Mux54 and Mux55 may co-operate as the output data selecting unit 31. The output data selecting unit 31 receives the data d0, d1, d2, and d3 as the parallel read data rd0, rd1, rd2, and rd3 that have been input. The output data selecting unit 31 performs selection from the data d0, d1, d2, and d3 in accordance with the first test signal Test1 and the second test signal Test2. Namely, the output data selecting unit 31 may select two of the data d0, d1, d2, and d3 in accordance with the first test signal Test1 and the second test signal Test2. For examples, the output data selecting unit 31 may select, but not limited to, the data d0 and d2. The output data selecting unit 31 may supply the selected data to the data output unit 30.

The latch circuits 10 and 11, the multiplexer Mux56, and the output buffer 12 may co-operate as the data output unit 30. The data output unit 30 receives the selected data from the output data selecting unit 31. The data output unit 30 performs serial output of the selected data at the rising and falling edges of the lock output signal clk_out. The serial output of the selected data appears on the data input output terminal DQ.

### Operation of Output Circuit:

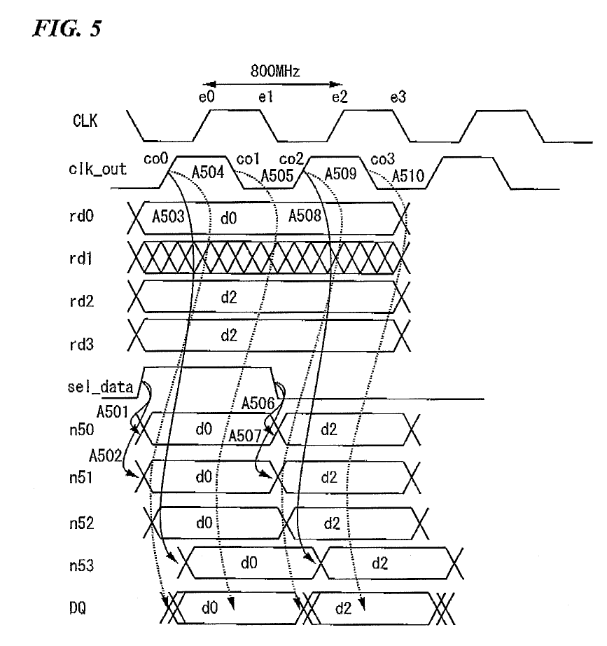

FIG. 5 is a timing chart illustrating operations of the output circuit of FIG. 4. The following descriptions will be described, assuming that the read data rd0, rd1, rd2, and rd3 have values which correspond to the data d0, x, d2 and d3, respectively, wherein “x” represents “defined”.

When the output data selecting signal se1_data is transitioned to “HIGH”, the multiplexer Mux50 selects the data d0, so that the multiplexer Mux50 outputs the selected data d0 as an output n50 (see A501), while the multiplexer Mux51 selects the data d0, so that the multiplexer Mux50 outputs the selected data d0 as an output n51 (see A502).

At the rising edge co0 of the clock output signal clk_out, namely when the clock output signal clk_out is transitioned to “HIGH”, the latch circuit 11 latches the data d0 that has been output from the multiplexer Mux51, so that the latch circuit 11 outputs the latched data d0 as an output n53 (see A503).

At the rising edge coo of the clock output signal clk_out, namely when the clock output signal clk_out is transitioned to “HIGH”, the multiplexer Mux56 selects the data d0 that has been output from the latch circuit 10, so that the multiplexer Mux56 supplies the selected data d0 through the output buffer 12 to the data input output terminal DQ (see A504). The clock output signal clk_out is synchronized with the clock signal CLK. The rising edge co0 of the clock output signal clk_out corresponds to the rising edge e0 of the clock signal CLK.

At the falling edge co1 of the clock output signal clk_out, namely when the clock output signal clk_out is transitioned to “LOW”, the multiplexer Mux56 selects the data d0 that has been output from the latch circuit 11, so that the multiplexer Mux56 supplies the selected data d0 through the output buffer 12 to the data input output terminal DQ (see A505).

When the output data selecting signal se1_data is transitioned to “LOW”, the multiplexer Mux50 selects the data d2, so that the multiplexer Mux50 outputs the selected data d2 as an output n50 (see A506), while the multiplexer Mux51 selects the data d2, so that the multiplexer Mux51 outputs the selected data d2 as an output n51 (see A507).

At the rising edge co2 of the clock output signal clk_out, namely when the clock output signal clk_out is transitioned to “HIGH”, the latch circuit 11 latches the data d2 that has been output from the multiplexer Mux51, so that the latch circuit 11 outputs the latched data d2 as an output n53 (see A508).

At the rising edge co2 of the clock output signal clk_out, namely when the clock output signal clk_out is transitioned to “HIGH”, the multiplexer Mux56 selects the data d2 that has been output from the latch circuit 10, so that the multiplexer Mux56 supplies the selected data d2 through the output buffer 12 to the data input output terminal DQ (see A509).

At the falling edge co1 of the clock output signal clk_out namely when the clock output signal clk_out is transitioned to “LOW”, the multiplexer Mux56 selects the data d2 that has been output from the latch circuit 11, so that the multiplexer Mux56 supplies the selected data d2 trough the output buffer 12 to the data input output terminal DQ (see A510).

In accordance with the output circuit, when the first test signal Test1 is “HIGH”, the multiplexers Mux50 and Mux51 select the read data rd0 and rd2 but do not select the undesired read data rd1, so that the multiplexers Mux50 and Mux51 output data d0 and d2 as the outputs n50 and n51, respectively.

The output circuit sequentially supplies the data d0, d1, d2 and d3 to the data input output terminal DQ in accordance with the transitions of the clock output signal clk_out between “HIGH” and “LOW”.

As described with reference to FIGS. 4 and 5, the output circuit receives the read data rd0, rd1, rd2, and rd3 which have been read out of memory cells, wherein the read data rd0, rd1, rd2, and rd3 correspond to write data wd0, wd1, wd2, and wd3 that had previously been written in the memory cells.

When a non-advanced low speed tester is used to test the semiconductor memory device that includes the conventional input circuit that is different from the input circuit of FIG. 1, the data d0, d0, d2 and d2 may be written in memory cells as the write data wd0, wd1, wd2, wd3. In some cases, the data d0, d0, d2, and d2 may not be normally written in the memory cells because the setup time or the hold time for writing data may be inadequate when the non-advanced low speed tester is used to input data into the conventional input circuit in the semiconductor memory device.

When the data are not normally written in memory cells, the read data rd0, rd1, rd2, and rd3 that have been read out of the memory cells way correspond to data values d0, x, d2 and d2, wherein “x” represents undefined data. This is caused by the facts that the data to be read out as the read data rd1 has been written with the inadequate setup time or hold time. The following descriptions will be made, assuming that the read data rd1 is “x” which represents undefined data.

When the data is not normally written, the stored data is undefined data. In this case, the undefined data is read out of the semiconductor memory device. The non-advanced low speed tester incorrectly determines that the semiconductor memory device would be defect. The use of the non-advanced low speed tester causes that the non-advanced low speed tester incorrectly determines the semiconductor memory device would be defective even the semiconductor memory device is actually non-defective.

It is possible to previously determine the write data which has been written with inadequate setup time and hold time. Thus, the read data which is estimated to be undefined can have been previously determined.

In the above-described example, the output data selecting unit 31 performs data selecting operation that selects the parallel read data so as to avoid selecting the read data that is estimated to be undefined. The data output unit 30 outputs the selected serial output data in synchronization with the clock output signal clk_out

When the write data to be stored in the memory cells may include undefined data that is data to be determined to be undefined by the non-advanced lower tester, the output circuit is adapted to select and output the normally written data, without selecting the undefined data. The normally written data free of any undefined data is supplied to the non-advanced low speed tester. The non-advanced low speed tester can normally determine the semiconductor memory device.

The output circuit is adapted to supply the same value data to the data input output terminal DQ at sequential sets of the rising and falling edges of a clock signal. The output data that is output from the output circuit has a period of time in which the output data value is constant so as to allow the non-advanced low speed tester to test the semiconductor memory device correctly and effectively. Namely, use of the output circuit described above allows the non-advanced low speed tester to be used to test the semiconductor memory device correctly and effectively.

Thus, the output circuit described above allows the non-advanced low speed tester to be used to write data and read the data, while the non-advanced low speed tester determines the semiconductor memory device correctly and effectively.

It is possible for normal mode operation that the output circuit is adapted to output, in accordance with the first test signal Test1 and the second test signal Test2, the data d0, d1, d2 and d3 as the read data rd0, rd1, rd2, and rd3 from the data input output terminal in synchronization with the rising and falling edges of the clock signal CLK, so that the output circuit can be used as an output circuit which is operable in normal mode.

When the input circuit of FIG. 1 is used in the semiconductor memory device, the write data to be stored in the memory cells is free of any undefined data, the use of the output circuit of FIG. 4 to avoid selection and output of any undefined data would not be essential or necessary. It would be, however, effective to use the input circuit of FIG. 1 in combination with the output circuit of FIG. 4 in order to allow the non-advanced low speed tester to test a peripheral circuit.

The term “unit” is used to describe a component, section or part of a device includes hardware and/or software that is constructed and/or programmed to carry out the desired function. Moreover, term “unit” in the claims should include any structure that can be utilized to carry out the function of that part of the present invention.

The term “circuit” is used to describe a component, section or part of a device includes hardware and/or software that is constructed and/or programmed to carry out the desired function. Moreover, term “circuit” in the claims should include any structure that can be utilized to carry out the function of that part of the present invention.

The terms “undefined data” in the specification and claims is used to describe data which is probably determined to be undefined by a tester that is used to test the semiconductor memory device. The tester may typically be a non-advanced low speed tester.

The terms “in synchronization with clock signal” or synchronized with clock signal” in the specification and claims are used to describe “in synchronization directly with clock signal” or synchronized directly with clock signal” or “in synchronization indirectly with clock signal” or synchronized indirectly with clock signal”.

Moreover, terms that are expressed as “means-plus function” in the claims should include any structure that can be utilized to carry out the function of that part of the present invention.

It is apparent that the present invention is not limited to the above embodiments, but may be modified and changed without departing from the scope and spirit of the invention.

What is claimed is:

1. A semiconductor memory device comprising:
a storing unit that stores serial input data synchronized with at least one of a first type edge and a second type edge of a clock signal; and
a selecting unit that receives the input data from the storing unit, the selecting unit selecting the input data, the selecting unit outputting the selected input data in parallel.

2. The semiconductor memory device according to claim 1, wherein the storing unit synchronously receives the input data from the outside at the first type edge and the second type edge of the clock signal.

3. The semiconductor memory device according to claim 1, further comprising:
a memory cell area,
wherein the selecting unit supplies the selected data to the memory cell area.

4. The semiconductor memory device according to claim 3, wherein the at least one of the first type edge and the second type edge of the clock signal is a timing such as to ensure an adequate setup time and an adequate hold time to store the input data in the memory cell area normally.

5. The semiconductor memory device according to claim 1, wherein the storing unit and the selecting unit cooperate as an input data storing and selecting unit for input selected input data into the memory cell area.

6. The semiconductor memory device according to claim 1, wherein the selecting unit selects one of the input data stored in synchronization with the first type edge of the clock signal and the input data stored in synchronization with the second type edge of the clock signal.

7. The semiconductor memory device according to claim 1, wherein the storing unit stores input data in synchronization with selected edges that are selected from the first type edges which are sequential.

8. The semiconductor memory device according to claim 1, wherein the storing unit stores input data in synchronization with selected edges that are selected from the second type edges which are sequential.

9. The semiconductor memory device according to claim 1, wherein the storing unit comprises:
a first storing circuit that stores the input data in synchronization with the first type edge of the clock signal; and
a second storing circuit that stores the input data in synchronization with the second type edge of the clock signal, and
wherein the selecting unit selects one of the input data stored in the first storing circuit and the input data stored in the second storing circuit.

10. The semiconductor memory device according to claim 9, wherein the storing unit further comprises:
a shift register that sequentially stores the input data stored in the first storing circuit and the input data stored in the second storing circuit in synchronization with one of the first type and second type edges, and
wherein the selecting unit select one of the input data stored in the first storing circuit, the input data stored in the second storing circuit, and the input data stored in the shift register.

11. The semiconductor memory device according to claim 10, further comprising:
a storing and output unit that receives the selected data from the selecting unit, the storing and output unit storing the selected data in accordance with a load data signal, the storing and output unit outputting the selected data in accordance with the load data signal.

12. The semiconductor memory device according to claim 11, wherein the shift register comprises:
a third storing circuit that receives the input data from the first storing circuit, the third storing circuit storing the input data in synchronization with one of the first type and second type edges of the clock signal; and
a fourth storing circuit that receives the input data from the second storing circuit, the fourth storing circuit storing the input data in synchronization with one of the first type and second type edges of the clock signal,
wherein the selecting unit comprises:
a first selecting circuit that selects, in accordance with a first selecting signal, one of the input data stored in the first storing circuit and the input data stored in the second storing circuit; and
a second selecting circuit that selects, in accordance with the first selecting signal, one of the input data stored in the third storing circuit and the input data stored in the fourth storing circuit, and
wherein the storing and output unit comprises:
a fifth storing circuit that receives the selected input data from the first selecting circuit, the fifth storing circuit storing the selected input data in accordance with the load data signal, and
a sixth storing circuit that receives the selected input data from the second selecting circuit, the sixth storing circuit storing the selected input data in accordance with the load data signal.

13. The semiconductor memory device according to claim 12, wherein the selecting unit further comprises:
a third selecting circuit that selects, in accordance with a second signal, one of the input data that stored in the first storing circuit and the input data that stored in the second storing circuit;
a fourth selecting circuit that selects, in accordance with the second signal, one of the input data that stored in the third storing circuit and the input data that stored in the fourth storing circuit, and
wherein the storing and output unit further comprises:
a seventh storing circuit that receives the selected input data from the third selecting circuit, the seventh storing circuit storing the selected input data in accordance with the load data signal, and
an eighth storing circuit that receives the selected input data from the fourth selecting circuit, the eighth storing circuit storing the selected input data in accordance with the load data signal.

14. A semiconductor memory device comprising:
a selecting unit that selects parallel output data; and
an output unit that receives the selected output data from the selecting unit, the output unit outputting the selected output data in serial in synchronization with first type and second type edges of a clock signal.

15. The semiconductor memory device according to claim 14, her comprising:
a memory cell area,
wherein the selecting unit receives the parallel output data from the memory cell area.

16. The semiconductor memory device according to claim 14, wherein the selecting unit and the outputting unit cooperate as an output data selecting and outputting unit for outputting selected output data from the memory cell area.

17. The semiconductor memory device according to claim 14, wherein the selecting unit selects the output data that have normally been stored in the memory cell area, without selecting the output data that are to be undefined.

18. The semiconductor memory device according to claim 14, wherein the selecting unit selects the output data that have been stored in the memory cell area with an adequate setup time and an adequate hold time to store normally, without selecting the output data that have been stored in the memory cell area with an inadequate setup time and an inadequate hold time.

19. The semiconductor memory device according to claim 14, wherein the selecting unit comprises:
a first selecting circuit that selects one of the parallel output data; and
a second selecting circuit that selects one of the parallel output data;
wherein the output unit comprises:
a first storing circuit that receives the selected output data from the first selecting circuit, the first storing circuit storing the selected output data in accordance with a first potential level of the clock signal;
a second storing circuit that receives the selected output data from the second selecting circuit, the second storing circuit storing the selected output data in accordance with a second potential level of the clock signal; and
a selecting circuit that selects one of the output data from the first storing circuit and the output data from the second storing circuit.

20. The semiconductor memory device according to claim 19, wherein the parallel output data includes first to fourth sets of output data,
wherein the selecting unit further comprises:
a third selecting circuit that selects the first set of output data or the second set of output data, the third selecting circuit outputting a first selected output data;
a fourth selecting circuit that selects the third set of output data or the fourth set of output data, the fourth selecting circuit outputting a second selected output data;
a fifth selecting circuit that selects the first set of output data or the second set of output data, the fifth selecting circuit outputting a third selected output data;
a sixth selecting circuit that selects the third set of output data or the fourth set of output data, the sixth selecting circuit outputting a fourth selected output data;
wherein the first selecting circuit selects the first selected output data or the second selected output data; and
wherein the second selecting circuit selects the third selected output data and the fourth selected output data.
